(19) United States
(12) Patent Application Publication
(10) Pub. No.: US 2025/0365891 A1
(43) Pub. Date: Nov. 27, 2025

(54) MANIFOLD AND SERVER HAVING THE MANIFOLD

(71) Applicant: Fulian Precision Electronics (Tianjin) Co., LTD., Tianjin (CN)

(72) Inventors: CHANG-JU WU, New Taipei (TW); Chih-Min Lin, New Taipei (TW)

(21) Appl. No.: 18/952,966

(22) Filed: Nov. 19, 2024

(30) Foreign Application Priority Data
May 24, 2024 (CN) 202410652893.1

(51) Int. Cl. H05K 7/20

(52) U.S. Cl. CPC H05K 7/20272; H05K 7/20763

(57) ABSTRACT

A rotatable manifold and a server having the manifold are disclosed. The manifold includes a base and a diverter member, and the base includes a first housing and a connecting shaft. The diverter member includes a second housing and a sleeve. By rotating the sleeve around the connecting shaft, the second housing can rotate relative to the first housing, thereby altering the orientation of the pipes connected to the second housing. The orientation of the pipes can be altered, enabling the pipes to be arranged as desired and reducing the total length of the pipes.

### FIELD

The subject matter herein generally relates to servers, and more particularly, to a manifold and a server having the manifold.

### BACKGROUND

Servers require cooling during operations, and the servers equipped with liquid cooling systems may have better cooling performance compared to servers with air-cooled systems.

In a liquid cooling system, manifolds are typically used to connect different pipes together, thereby diverting the coolant within the pipes. Existing manifolds, however, do not allow for changes in orientations of the pipes, and in inflexible in arranging the pipes according to design preferences, and in using pipes having longer total lengths, in particular.

Therefore, there is room for improvement in the art.

### BRIEF DESCRIPTION OF THE DRAWINGS

Implementations of the present disclosure will now be described, by way of embodiments only, with reference to the attached figures.

FIG. 1 is a diagrammatic view of a server according to an embodiment of the present disclosure.

FIG. 2 is a diagrammatic view of an embodiment of a manifold of the server of FIG. 1 in a certain state.

FIG. 3 is a diagrammatic view of the manifold of FIG. 2 in another state.

FIG. 4 is an exploded view of the manifold of FIG. 2.

FIG. 5 is an exploded view of the manifold of FIG. 2, viewed from another angle.

FIG. 6 is a diagrammatic view of an embodiment a base of the manifold shown in FIG. 2.

FIG. 7 is a diagrammatic view of an embodiment of a diverter member of the manifold shown in FIG. 2.

FIG. 8 is a cross-sectional view of the manifold of FIG. 2.

### DETAILED DESCRIPTION

The technical solution of the present application will be described in detail below with reference to the drawings. It is evident that the described embodiments are merely a portion of the possible implementations of the present application, and do not represent all possible embodiments.

It should be noted that when a component is referred to as being “connect” or “mounted on” another component, it may be directly on the other component or there may also be an intervening component. When a component is considered to be “set on” another component, it may be in direct contact with the other component or there may also be an intervening component. The terms “vertical” “horizontal” “left” “right” and similar expressions used herein are solely for purposes of illustration.

In this application, descriptions such as “first”, “second” etc. are only used for description purposes and should not be understood as indicating or implying their relative importance or implying the number of indicated technical features. The term “vertical” is used to describe an ideal state between two components. In actual production or use, there may be a state that approximates vertical between the two components. The two components described as “vertical” may not be absolutely straight lines or planes, they may also be approximately straight or planar. From a macroscopic perspective, if the overall extension direction is straight or planar, the components can be considered as “straight” or “planar”.

Unless otherwise defined, all technical and scientific terms used herein have the same meaning as commonly understood by persons skill in the art. The terms used herein are only for the purpose of describing specific embodiments, and not intended to limit the embodiments of the present application.

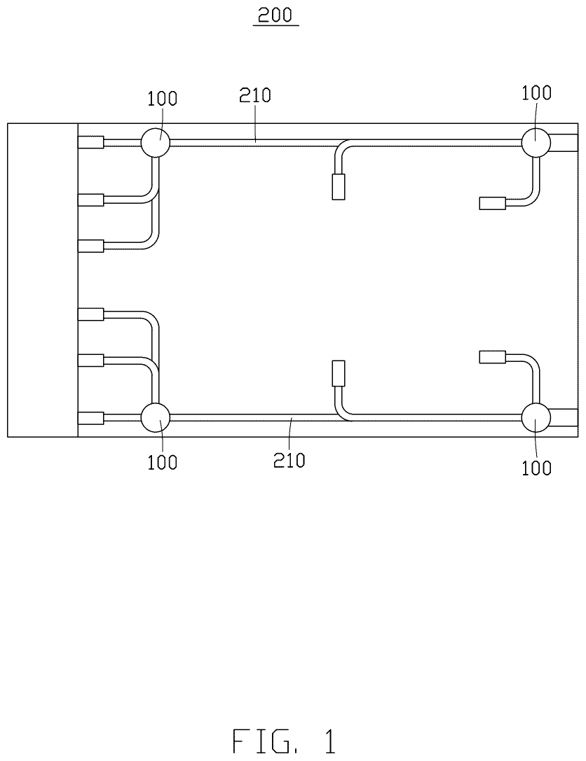

Referring to FIG. 1, an embodiment of the present application provides a server 200 including multiple pipes 210 and at least one manifold 100. The multiple pipes 210 are connected to each manifold 100 and allow a coolant to flow therethrough. The manifold 100 is configured to control the flow direction of the coolant within the pipes 210, thereby reducing the bending of the pipes 210. Thus, a decrease in the total length of the pipelines 210 and an increase in the flow velocity of the coolant are achieved, thereby enhancing the cooling efficiency of the server 200.

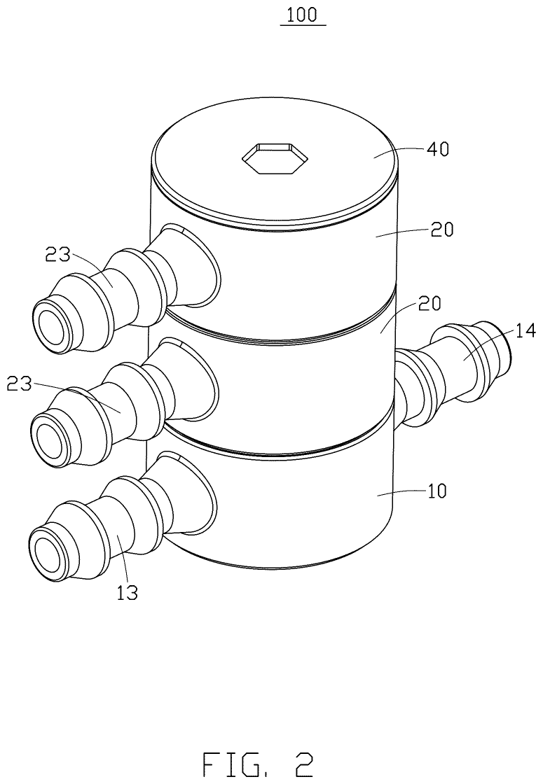

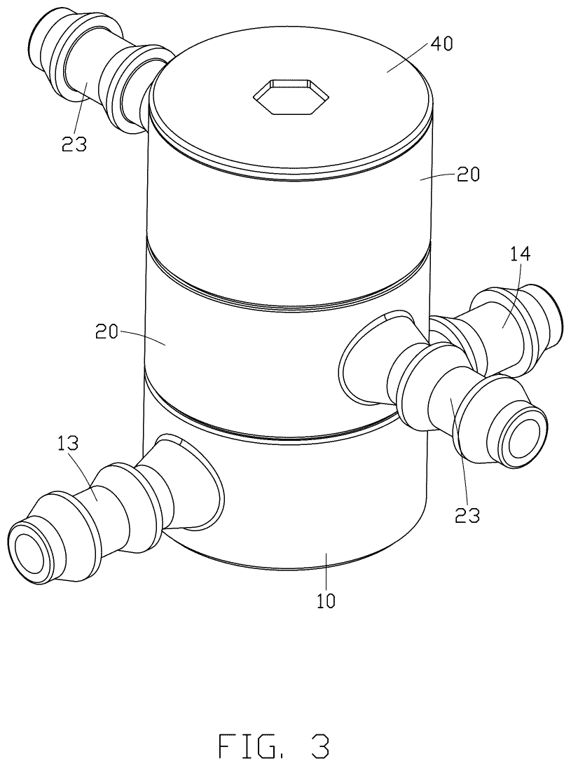

Referring to FIGS. 2 and 3, the manifold 100 includes a base 10 and at least one diverter member 20. Each of the diverted member 20 is rotatably connected to the base 10, and the base 10 and the diverter member 20 cooperatively define a sealed space. In some embodiments, there may be two or more diverter members 20, which are stacked sequentially on the base 10. Each of the base 10 and the diverter member 20 is used to connect one of the pipes 210, and the sealed space communicates with the pipes 210. The coolant can flow into the sealed space through one or more pipes 210, and then be discharged from the sealed space through another pipes 210, thereby removing heat from the server 200.

When using a nonrotatable and unidirectional manifold, the pipes 210 need to be bent to change the orientation of the pipes 210. In the present disclosure, since the diverter member 20 can rotate relative to the base 10, the orientation of the pipes 210 connected to the diverter member 20 can be changed. The manifold 100 of the present disclosure allows for arbitrary changes in the orientation of the pipes 210, thereby enabling the pipes 210 to be arranged as desired and reducing the total length of the pipes 210.

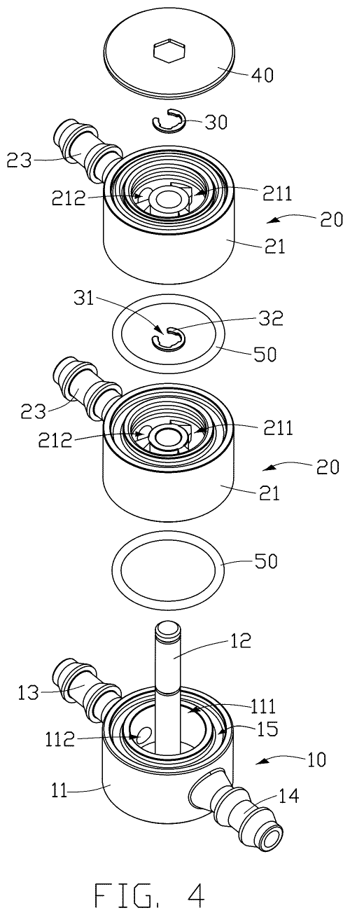

Referring to FIGS. 4 to 6, the base 10 includes a first housing 11. The first housing 11 defines a first cavity 111, a first fluid exchange port 112, and a second fluid exchange port 113. Each of the first fluid exchange port 112 and the second fluid exchange port 113 communicates with the first cavity 111. Each of the first fluid exchange port 112 and the second fluid exchange port 113 are configured for connecting to one of the pipes 210, such that the pipe 210 can communicate with the first cavity 111.

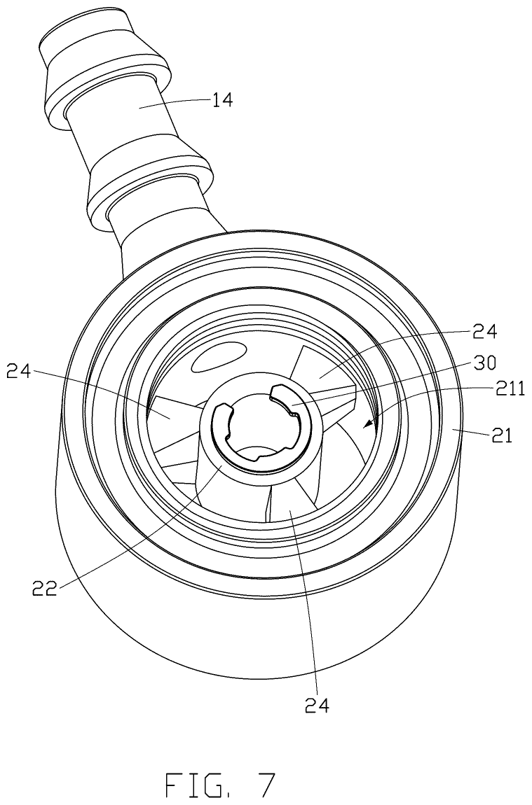

Referring to FIGS. 4 and 7, the diverter member 20 includes a second housing 21. The second housing 21 defines a second cavity 211 and a third fluid exchange port 212 communicating with the second cavity 211. The third fluid exchange port 212 is configured for connecting to one of the pipes 210, such that the pipe 210 can communicate with the second cavity 211. The second housing 21 is coaxially arranged with the first housing 11. The second housing 21 and the first housing 11 are sealed, and two adjacent second housings 21 are also sealed, so that the second cavity 211 and the first cavity 111 enclose the sealed space to prevent leakage of the coolant.

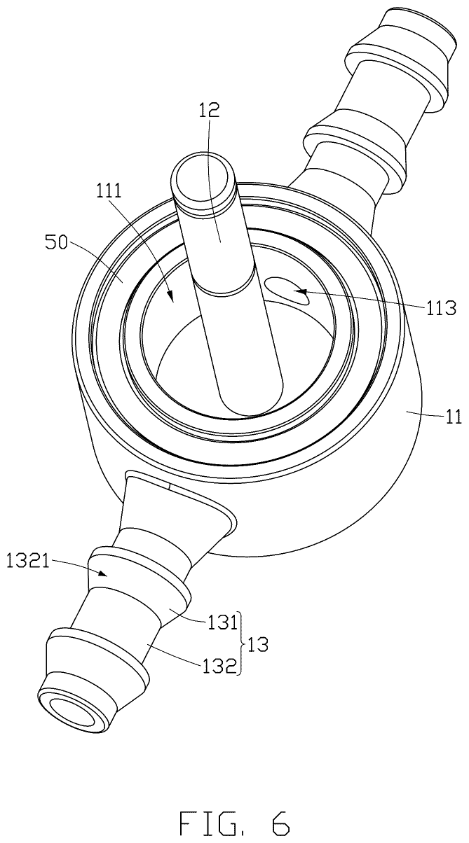

Referring to FIGS. 4 and 6, in some embodiments, the base 10 further includes a connecting shaft 12. One end of the connecting shaft 12 is located within the first cavity 111 and connected to the first housing 11, and another end of the connecting shaft 12 extends out of the first cavity 111 along an axial direction of the base 10. The diverter member 20 further includes a sleeve 22. The sleeve 22 is located within the second cavity 211 and connected to the second housing 21. The sleeve 22 is sleeved on the connecting shaft 12 and can rotate around the connecting shaft 12. The second housing 21 is coaxially arranged with the first housing 11 through the connection of the connecting shaft 12 and the sleeve 22. The connection between the sleeve 22 and the connecting shaft 12 is simple, and the first housing 11 and the second housing 21 can be sealed during the rotation of the diverter member 20, thereby preventing leakage of the coolant to improve the sealing performance.

When it is necessary to change the orientation of the pipe 210 connected to the third fluid exchange port 212, the diverter member 20 is rotated relative to the base 10 (at this time, the sleeve 22 rotates around the connecting shaft 12, and the second housing 21 rotates relative to the first housing 11), and the orientation of the pipeline 210 can be changed.

In some embodiments, both of the first housing 11 and the second housing 21 are cylindrical, which ensuring the sealing performance of the first housing 11 and the second housing 21 during the relative rotation between the first housing 11 and the second housing 21.

In some embodiments, the sidewall of the first housing 11 is rotatably connected to the second housing 21. In at least one embodiment, a sliding groove is defined on the top of the first housing 11, and a sliding block is arranged on the bottom of the second housing 21. The sliding block is slidably connected to the sliding groove, thereby achieving the relative rotation between the first housing 11 and the second housing 21.

In some embodiments, the sleeve 22 is cylindrical, and the connecting shaft 12 is also cylindrical. The inner diameter of the sleeve 22 is equal to the outer diameter of the connecting shaft 12, thereby allowing the sleeve 22 to be sleeved on the connecting shaft 12 and rotate around the connecting shaft 12.

Referring to FIGS. 4, 5 and 8, in some embodiments, the manifold 100 further includes a sealing member 40. The sealing member 40 is used to seal the first cavity 111 and the second cavity 211. The sealing member 40 is connected to one side of the diverter member 20 facing away from the base 10. When there are multiple diverter members 20, the sealing element 40 is connected to one of the diverter members 20 that farthest from the base 10.

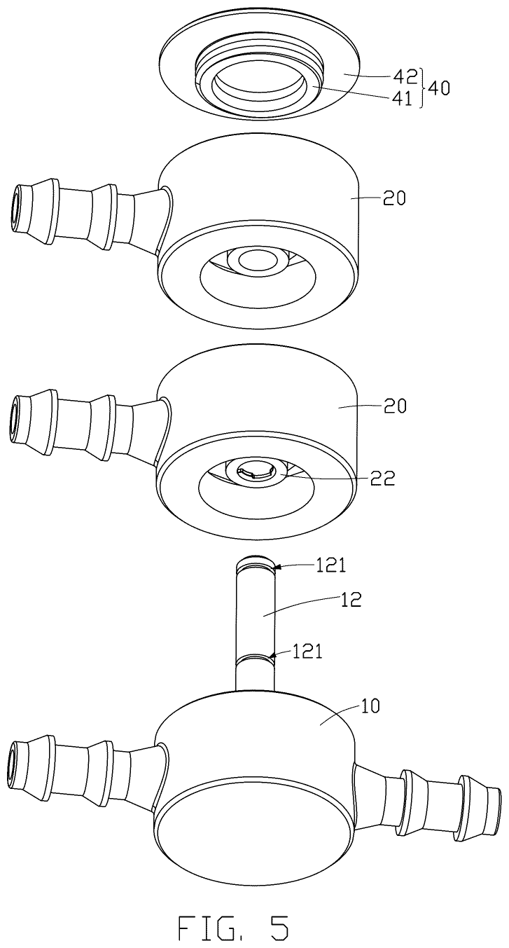

Furthermore, as shown in FIG. 5, the sealing member 40 includes a connecting portion 41 and a cover plate 42 fixed to the connecting portion 41. The connecting portion 41 extends in a direction parallel to the axial direction of the second housing 21 and further extends into the second housing 21. The second housing 21 may be sleeved on the outer circumference of the connecting portion 41 and rotatably connected to the connecting portion 41. The cover plate 42 is arranged at the end of the second housing 21 facing away from the first housing 11, thereby sealing the first cavity 111 and the second cavity 211.

In some embodiments, both of the second housing 21 and the connecting portion 41 are cylindrical. The inner wall of the end of the second housing 21 near the sealing member 40 defines internal threads, and the outer wall of the connecting portion 41 defines external threads. By engaging the external threads with the internal threads, the connecting portion 41 gradually screws into the second housing 21, thereby achieving the connection between the second housing 21 and the sealing member 40.

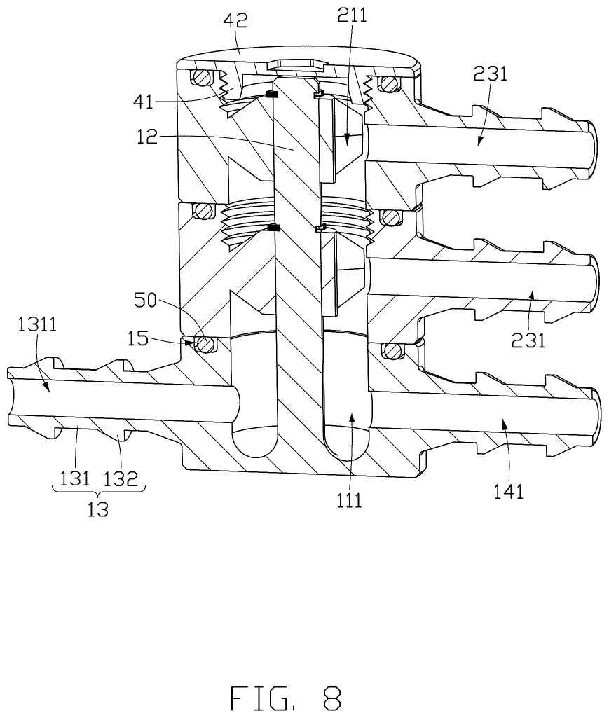

Referring to FIGS. 4 and 8, in some embodiments, the manifold 100 further includes at least one gasket 50. Annular grooves 15 are defined between the first housing 11 and the second housing 21, as well as between two adjacent second housings 21. For example, one annular groove 15 is defined on the surface of the first housing 11 facing the second housing 21, and one annular groove 15 is defined on the surface of one second housing 21 facing to an adjacent second housing 21. Each annular groove 15 is provided with one gasket 50, thereby sealing the junctions between the first housing 11 and the second housing 21, as well as between the two adjacent second housings 21, to prevent leakage of the coolant.

In some embodiments, a portion of the annular groove 15 is defined on the first housing 11, and another portion of the annular groove 15 is defined on the second housing 21. When the gasket 50 is placed in the annular groove 15, the central area of the gasket 50 aligns with the junction between the first housing 11 and the second housing 21, thereby improving the sealing effect.

Referring to FIGS. 4, 5, and 7, in some embodiments, the manifold 100 further includes a retaining ring 30 and a clamping groove 121. The retaining ring 30 is located on the side of the sleeve 22 that faces away from the first housing 11. The clamping groove 121 is defined on the connecting shaft 12 and used for engaging with the retaining ring 30. The engagement between the retaining ring 30 and the clamping groove 121 can limit the sleeve 22 from moving axially relative to the connecting shaft 12.

Furthermore, the retaining ring 30 may be C-shaped and defines an opening 31, and the clamping groove 121 may be annular. When the second housing 21 and the first housing 11 are connected through the sleeve 22 and the connecting shaft 12, the clamping groove 121 is located above the sleeve 22. The retaining ring 30 is placed over the retaining groove 121 through the opening 31, with the lower surface of the retaining ring 30 abutting the upper surface of the sleeve 22 to prevent the sleeve 22 from moving upwards. Thus, the retaining ring 30 can limit the second housing 21 from moving away from the first housing 11, thereby allowing the second housing 21 to only rotate relative to the first housing 11 around the connecting shaft 12.

In some embodiments, the retaining ring 30 may also be an insertion member, and an insertion groove is defined on the connecting shaft 12. The insertion member is inserted into the insertion groove to limit the second housing 21 from moving away from the first housing 11.

Referring to FIGS. 4 and 6, in some embodiments, each of the first fluid exchange port 112, the second fluid exchange port 113, and the third fluid exchange port 212 is perpendicular to the axial direction of the first housing 11 or the second housing 21. Therefore, the pipes 210 connected to the first fluid exchange port 112 and the third fluid exchange port 212, or pipes 210 connected to the second fluid exchange port 113 and the third fluid exchange port 212, or pipes 210 connected to two third fluid exchange ports 212, can be spaced apart in the axial direction of the first housing 11. Each of the pipes 210 extends in a horizontal direction. In this embodiment, the axial direction is the vertical direction, and the connecting shaft 12 extends along the vertical direction.

Referring to FIGS. 2, 6, and 8, in some embodiments, the base 10 further includes a first connecting member 13 and a second connecting member 14. Both of the first connecting member 13 and the second connecting member 14 are connected to the first housing 11. The first connecting member 13 includes a first main body 131 and a first convex ring 132. The first main body 131 extends in a direction perpendicular to the axial direction of the first housing 11, and the first convex ring 132 is annularly disposed around the outer perimeter of the first main body 131. When the first connecting member 13 is inserted into the pipe 210, the outer wall of the first convex ring 132 contacts the inner wall of the pipe 210, thereby stabilizing the connection between the first connecting member 13 and the pipe 210. The first connecting member 13 defines a first channel 1311 communicating with the first fluid exchange port 112, and the first channel 1311 penetrates the first main body 131.

In some embodiments, there are multiple first convex rings 132. The multiple first convex rings 132 are spaced apart and disposed around the outer perimeter of the first main body 131, such that the sealing between the pipe 210 and the first connecting member 13 is enhanced.

If the first connecting member is not equipped with the first convex ring(s), there would be gaps between the outer wall of the first main body and the inner wall of the pipe. These gaps will affect the connection between the connecting member and the pipe. Therefore, the first connecting member 13 equipped with the first convex ring(s) 132 is easier to connect to and disconnect from the pipe 210.

Referring to FIG. 6, in some embodiments, the surface of the first convex ring 132 facing away from the first cavity 111 is an inclined surface 1321. The inclined surface 1321 is inclined towards the side of the first connecting member 13 facing away from the first cavity 111, that is, the highest end of the inclined surface 1321 is closer to the first cavity 111 compared to the lowest end of the inclined surface 1321. When connecting the pipe 210 to the first connecting member 13, the pipe 210 gradually moves from the lowest end of the inclined surface 1321 to the highest end until the first connecting member 13 is fully inserted into the pipe 210. The inclined surface 1321 serves as a guiding feature for the connection between the pipe 210 and the first connecting member 13.

Referring to FIGS. 2 and 8, in some embodiments, the second connecting member 14 defines a second channel 141 communicating with the second fluid exchange port 113, and the diverter member 20 further includes a third connecting member 23. The third connecting member 23 is connected to the second housing 21, and the third connecting member 23 defines a third channel 231 communicating with the third fluid exchange port 212. The first connecting member 13, the second connecting member 14, and the third connecting member 23 all extend in a direction perpendicular to the axial direction of the base 10 for inserting pipes 210, and the above three connecting members all extend in a direction facing away from the first cavity 111. Compared to directly inserting the pipe 210 into the first fluid exchange port 112, sleeving the pipe 210 onto the first connecting member 13 provides a more stable connection between the pipe 210 and the first fluid exchange port 112. The connected pipe 210 is less likely to fall off, and the coolant is less likely to overflow from the connection point between the pipe 210 and the first fluid exchange port 112.

In some embodiments, the structures of the second connecting member 14 and the third connecting member 23 are identical to that of the first connecting member 13, and thus will not be further described here.

Referring to FIG. 7, in some embodiments, the diverter member 20 further includes three ribs 24. The three ribs 24 are disposed within the second cavity 211. One end of each rib 24 is connected to the sleeve 22, and another end of each rib 24 is connected to the inner wall of the second housing 21. The three ribs 24 are evenly spaced apart from each other to support the sleeve 22, thereby allowing the sleeve 22 to be stably connected inside the second housing 21.

The above descriptions are some specific embodiments of the present application, but the actual application process cannot be limited only to these embodiments. For those of ordinary skill in the art, other modifications and changes made according to the technical concept of the present application should all belong to the protection scope of the present application.

What is claimed is:

1. A manifold comprising:
a base comprising a first housing and a connecting shaft, wherein the first housing defines a first cavity, a first fluid exchange port, and a second fluid exchange port, each of the first fluid exchange port and the second fluid exchange port communicates with the first cavity; one end of the connecting shaft is arranged in the first cavity and connected to the first housing, and another end of the connecting shaft protrudes from the first cavity along an axial direction of the base; and
a diverter member comprising a second housing and a sleeve, wherein the second housing defines a second cavity and a third fluid exchange port communicating with the second cavity, the sleeve is arranged in the second cavity and connected to the second housing, the sleeve is rotatably sleeved on the connecting shaft of the base; the second housing is connected to and coaxial with the first housing, the second cavity communicates with the first cavity, and each of the first fluid exchange port, the second fluid exchange port, and the third fluid exchange port is configured to be connected to a pipe.

2. The manifold of claim 1, further comprising a retaining ring, wherein a side of the connecting shaft away from the first housing defines a clamping groove, and the retaining ring is engaged with the clamping groove to limit an axial movement of the sleeve relative to the connecting shaft.

3. The manifold of claim 1, further comprising a gasket, wherein an annular groove is defined between the first housing and the second housing, and the gasket is received in the annular groove.

4. The manifold of claim 1, further comprising a sealing member, wherein the sealing member comprises a connecting portion and a cover plate connected to the connecting portion, the second housing is sleeved on an outer circumference of the connecting portion and connected to the connecting portion, and the cover plate is arranged at one end of the second housing away from the first housing to seal the second cavity.

5. The manifold of claim 1, wherein each of the first fluid exchange port, the second fluid exchange port, and the third fluid exchange port is perpendicular to the axial direction of the base.

6. The manifold of claim 1, wherein the base further comprises a first connecting member and a second connecting member, each of the first connecting member and the second connecting member is connected to the first housing, the first connecting member defines a first channel communicating with the first fluid exchange port, and the second connecting member defines a second channel communicating with the second fluid exchange port.

7. The manifold of claim 6, wherein the diverter member further comprises a third connecting member connected to the second housing, and the third connecting member defines a third channel communicating with the third fluid exchange port.

8. The manifold of claim 7, wherein each of the first connecting member, the second connecting member, and the third connecting member extends in a direction perpendicular to the axial direction of the base, and each of the first connecting member, the second connecting member, and the third connecting member extends in a direction away from the first cavity.

9. The manifold of claim 6, wherein the first connecting member comprises a first main body and a first convex ring, the first channel penetrates the first main body, and the first convex ring is sleeved on an outer perimeter of the first main body, such that an inner wall of the pipe is in contact with an outer wall of the first convex ring.

10. The manifold of claim 9, wherein a surface of the first convex ring facing away from the first cavity is an inclined surface, and the inclined surface is inclined towards a side of the first connecting member facing away from the first cavity.

11. The manifold of claim 1, wherein the diverter member further comprises at least one rib arranged in the second cavity, one end of each rib of the at least one rib is connected to the sleeve, and another end of the rib is connected to an inner wall of the second housing.

12. The manifold of claim 11, wherein the at least one rib comprises three ribs spaced apart from each other.

13. A server comprising:
a manifold comprising:
a base comprising a first housing and a connecting shaft, wherein the first housing defines a first cavity, a first fluid exchange port, and a second fluid exchange port, each of the first fluid exchange port and the second fluid exchange port communicates with the first cavity; one end of the connecting shaft is arranged in the first cavity and connected to the first housing, and another end of the connecting shaft protrudes from of the first cavity along an axial direction of the base; and
a diverter member comprising a second housing and a sleeve, wherein the second housing defines a second cavity and a third fluid exchange port communicating with the second cavity, the sleeve is arranged in the second cavity and connected to the second housing, the sleeve is rotatably sleeved on the connecting shaft of the base; the second housing is connected to and coaxial with the first housing, the second cavity communicates with the first cavity; and
a pipe connected to the manifold.

14. The server of claim 13, wherein the manifold further comprises a retaining ring, a side of the connecting shaft away from the first housing defines a clamping groove, and the retaining ring is engaged with the clamping groove to limit an axial movement of the sleeve relative to the connecting shaft.

15. The server of claim 13, wherein the manifold further comprises a gasket, an annular groove is defined between the first housing and the second housing, and the gasket is received in the groove.

16. The server of claim 13, wherein the manifold further comprises a sealing member, the sealing member comprises a connecting portion and a cover plate connected to the connecting portion, the second housing is sleeved on an outer circumference of the connecting portion and connected to the connecting portion, and the cover plate is arranged at one end of the second housing away from the first housing to seal the second cavity.

17. The server of claim 13, wherein each of the first fluid exchange port, the second fluid exchange port 113, and the third fluid exchange port is perpendicular to the axial direction of the base.

18. The server of claim 13, wherein the base further comprises a first connecting member and a second connecting member, each of the first connecting member and the second connecting member is connected to the first housing, the first connecting member defines a first channel communicating with the first fluid exchange port, and the second connecting member defines a second channel communicating with the second fluid exchange port.

19. The server of claim 18, wherein the diverter member further comprises a third connecting member connected to the second housing, and the third connecting member defines a third channel communicating with the third fluid exchange port.

20. The server of claim 19, wherein each of the first connecting member, the second connecting member, and the third connecting member extends in a direction perpendicular to the axial direction of the base, and each of the first connecting member, the second connecting member, and the third connecting member extends in a direction away from the first cavity.
